(19) United States
(12) Patent Application Publication
(10) Pub. No.: US 2002/0039830 A1
(43) Pub. Date: Apr. 4, 2002

(54) Salicidation process for a fully depleted silicon-on-insulator device

(76) Inventors: Wen-Kuan Yeh, Chupei City (TW); Tony Lin, Kaohsiung Hsien (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 09/827,474

(22) Filed: Apr. 6, 2001

Related U.S. Application Data
(62) Division of application No. 09/678,039, filed on Oct. 3, 2000.

(30) Foreign Application Priority Data
Sep. 18, 2000 (TW) 89119116

(51) Int. Cl. H01L 21/36

(52) U.S. Cl. 438/479

(57) ABSTRACT

A salicidation process for a SOI device, comprising a polysilicon gate formed thereon is described. Source/drain regions are formed in the SOI substrate besides the sides of the gate structure. A selective epitaxal growth silicon layer is formed on the source/drain regions and on the gate structure, followed by forming a metal salicide layer on source/drain regions and the gate structure.

### CROSS-REFERENCE TO RELATED APPLICATION

This application claims the priority benefit of Taiwan application serial no. 89119116, filed Sep. 18, 2000.

### BACKGROUND OF THE INVENTION

1. Field of the Invention

The present invention relates to a fabrication method for a SOI device. More particularly, the present invention relates to a salicidation process for a SOI device.

2. Description of the Related Art

In recent years, integrated circuits using a silicon-on-insulator (SOI) substrate have evolved. The SOI technology entails building silicon devices, such as transistors, on an insulated substrate rather than on a silicon substrate. In another words, the SOI substrate has an interior, insulating layer formed closed to the wafer surface, which separate the device from the main body of the substrate.

Compared with devices formed on a bulk silicon substrate, devices formed on a SOI substrate, especially on a fully depleted SOI substrate, have better functional properties. The reported improvements include providing a superior electrical isolation between adjacent components, which, in turns allows closer component spacing and integrated-circuit size reductions, and reducing integrated-circuit capacitance, which, in turns, enhances operating speeds. Additionally, the SOI substrate enables the use of lower operating voltages, which significantly reduces the power consumption.

In the deep sub-micron integrated circuit technology, the line width, the contact area and the contact depth are continuously being reduced. To effectively raise the quality of a device, to decrease the resistance and to reduce the RC delay time due to a high resistance and capacitance, the fabrication of the MOS transistor tends to employ a silicide layer to reduce the contact resistance at the gate and the source/drain region.

The conventional self-aligned silicidation (salicidation) process includes depositing a metal layer, for example, cobalt, on a SOI substrate, covering the gate and the surface of the source/drain region. A thermal process is conducted for the metal layer to react with the silicon on the surface of the source/drain region and the gate to form a salicide layer on the surface of the gate and the source/drain region. The unreacted metal layer is then removed by wet etching to complete the salicidation process.

Since the thickness of the silicon layer of a SOI substrate, especially for a fully depleted SOI substrate, is very thin, for example, less than 500 angstroms, many of the silicon atoms are consumed during the salicidation process. This phenomenon is especially prominent when forming cobalt salicide film (CoSi₂), for example, every 100 angstroms thick of cobalt consumes 360 angstroms thick of silicon, leading to dislocation or fracture of the cobalt salicide film, which further gives rise to higher source/drain resistance and lower operating speed of the device.

### SUMMARY OF THE INVENTION

Based on the foregoing, a salicidation process for a fully depleted SOI device is provided, wherein a better quality of the salicide film is formed on the SOI substrate.

According to a preferred embodiment of the present invention, a SOI substrate comprising a polysilicon gate structure is provided. Source/drain regions are formed in the SOI substrate beside the side of the gate structure. A selective epitaxial growth silicon layer is then formed on the gate structure and the source/drain regions, followed by performing a salidation process.

Accordingly, the SEG silicon layer formed on the source/drain region provides sufficient silicon atoms for the subsequent salicidation process. A better quality of the salicide film is formed on the SOI substrate, obviating the problem of dislocation and fracture of the salicide film.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the present invention, and are incorporated in and constitute a part of this specification. The drawings illustrate embodiments of the invention and, together with the description, serve to explain the principles of the invention. In the drawings,

FIGS. 1A-1C are schematic, cross-sectional views showing the manufacturing of a SOI device according to a preferred embodiment of the present invention.

### DESCRIPTION OF THE PREFERRED EMBODIMENT

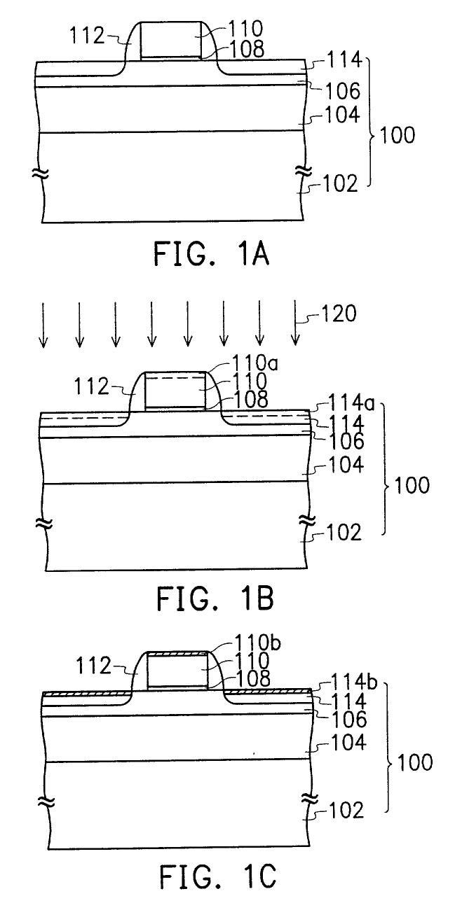

The manufacturing of a SOI device for integrated circuits, respectively in accordance with the present invention is described with reference to FIGS. 1A to 1C.

Referring to FIG. 1A, a silicon-on-insulator (SOI) substrate 100 is provided. The SOI substrate 100 can be formed using one of many conventional techniques, including separating by implantation of oxygen (SIMOX), wherein oxygen is implanted at a desired depth into a silicon wafer. The wafer is then subjected to an annealing to form a buried silicon oxide layer having an outward monocrystalline silicon layer thereover. A more costly method in forming the SOI substrate is the bonded and etchback SOI (BESOI) technique, wherein an insulation layer is formed on the top surface of a silicon wafer. An entire surface of another silicon wafer is bonded onto the insulation layer, essentially sandwiching the insulation layer between the silicon wafers. One of the silicon wafers is then ground down to a thin silicon layer to form a SOI substrate. A similar method, known as the “smart-cut” method, in which a thick portion of one effect is effectively sliced off, leaving a thin slice of silicon to cover the entire insulation layer and saving the sliced off thick portion for use in another silicon-insulator-silicon sandwich. As shown in FIG. 1A, the SOI substrate 100 comprises a silicon wafer 102 and an insulation layer 104, generally an oxide layer, on the silicon wafer 102. A moncrystalline silicon layer 106, less than 500 angstroms thick is formed above the insulation layer 104.

Still referring to FIG. 1A, a gate oxide layer 108 is formed on the SOI substrate 100, for example, by thermal oxidation, and a polysilicon gate electrode 110 is formed on the gate oxide layer 108. The polysilicon gate electrode 110 is formed by depositing a layer of undoped polysilicon (not shown in Figure) over the substrate, typically using low pressure chemical vapor deposition (LPCVD), implanting impurities into the polysilicon and annealing to activate the impurities and to render the polysilicon conductive. The polysilicon layer is then patterned using conventional photolithography.

Subsequently, insulating spacers 112, such as silicon nitride spacers of about 1000 angstroms wide, are formed on the sidewalls of the polysilicon gate electrode 110 and the gate oxide layer 108. The insulating spacers 112 are formed by, for example, first depositing a layer of chemically vapor deposited (CVD) silicon nitride layer over the resulting structure described above and then anisotropically etching back the silicon nitride layer to form the insulating spacers 112. Further using the spacers 112 and the polysilicon gate electrode 104 as masks, a heavy dosage of impurity is implanted into the SOI substrate 100 to form the source/drain regions 114 in the substrate 100 besides the sides of the insulating spacers 112.

Referring to FIG. 1B, a selective epitaxial growth (SEG) is conducted to form amorphous silicon layers 116 and 118, respectively on the gate electrode 110 and the source/drain regions 114, respectively. The SEG process is conducted, for example, using Si₂H₆ as a gas source, at a temperature of about 800 degrees Celsius to about 900 degrees Celsius. The SEG process is continued until the amorphous silicon layer 118 is about 100 to 600 angstroms thick. The amorphous silicon layer 118 formed on the source/drain regions 114 thus provides additional silicon atoms for the subsequent salicidation process.

Continuing to FIG. 1C, a conformal metal layer (not shown in Figure) is formed on the substrate 100. The metal layer, which includes cobalt or titanium, is formed by, for example, by sputtering deposition. A thermal process, for example, a rapid thermal process (RTP) is conducted, allowing the amorphous silicon layers 116, 118 on the surfaces of the gate electrode 110 and the source/drain regions 112 to form metal salicide layers 120, 122. A dry or wet etching is further conducted to remove the unreacted metal layer.

Based on the foregoing, the present invention provides a larger processing windows of the salicidation process for the fully depleted SOI device, wherein SEG silicon layers are formed on the source/drain region and the gate electrode to provide sufficient silicon atoms for the subsequent salicidation process. A better qulaity of the salicide film, especially for a cobalt-salicide film, is thus formed, obviating the problems of dislocation or fracture of the salicide film and a higher source/drain resistance.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabrication method for a silicon-on-insulator (SOI) device, comprising:
providing a fully depleted SOI substrate;
forming a gate structure on the SOI substrate having a spacer on a sidewall of the gate structure, wherein the gate structure comprises a gate oxide layer and a polysilicon gate electrode;
forming a source/drain region in the SOI substrate beside the spacer of the gate structure;
forming a selective epitaxial growth (SEG) silicon layer on the gate structure and on the source/drain region, wherein a thickness of the SEG silicon layer is sufficient to prevent dislocation and fracture of a subsequently formed metal salicide layer; and
forming the metal salicide layer on the gate structure and on the source/drain region.

2. The method according to claim 1, wherein providing the fully depleted SOI substrate further comprises:
providing a silicon wafer;
forming an insulation layer on the silicon wafer; and
forming a monocrystalline silicon layer above the insulation layer, wherein a thickness of the monocrystalline silicon layer is less than 500 angstroms.

3. The method according to claim 1, wherein the thickness of the selective epitaxial growth silicon layer is about 100 to 600 angstroms thick.

4. The method according to claim 1, wherein the formation of the metal salicide layer further comprises:
forming a conformal metal layer on the SOI substrate;
performing a thermal process to convert a portion of the metal layer into the metal salicide layer; and
removing an unreacted metal layer.

5. The method according to claim 1, wherein the metal salicide layer includes a cobalt salicide layer.

6. The method according to claim 1, wherein the metal salicide layer includes a titanium salicide layer.

7. A salicidation process for a SOI device, comprising:
providing a gate structure on a SOI substrate, wherein a source/drain region is formed in the SOI substrate beside the gate structure;
forming a silicon layer on the source/drain region and on the gate structure;
forming a metal layer on the silicon layer; and
performing a thermal process to form a metal salicide layer on the source/drain region and the gate structure.

8. The process according to claim 7, wherein a thickness of the silicon layer is sufficient to provide additional silicon atoms for the formation of a non-fractured metal salicide layer.

9. The process according to claim 7, wherein the silicon layer is about 100 angstroms to 600 angstroms thick.

10. The process according to claim 7, wherein the silicon layer is formed by a selective epitaxial growth process

11. The process according to claim 7, wherein the metal salicide layer includes a cobalt salicide layer.

12. The process according to claim 7, wherein the metal salicide layer includes a titanium salicide layer.
